(19) United States
(12) Patent Application Publication
(10) Pub. No.: US 2009/0029506 A1
(43) Pub. Date: Jan. 29, 2009

(54) METHOD OF MANUFACTURING SEMICONDUCTOR DEVICE

(75) Inventors: Tomoharu Fujii, Nagano-shi (JP); Yuichiro Shimizu, Nagano-shi (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD., Nagano-shi (JP)

(21) Appl. No.: 12/026,856

(22) Filed: Feb. 6, 2008

(30) Foreign Application Priority Data
Feb. 7, 2007 (JP) 2007-028108

(51) Int. Cl. H01L 21/56

(52) U.S. Cl. 438/127; 257/E21.502

(57) ABSTRACT

In a method of manufacturing a semiconductor device 10 including a wiring board 11 having a ground terminal 38, a semiconductor chip 12 and passive components 14 and 15 which are electronic components mounted on the wiring board 11, and a sealing resin 19 containing a silica filler for sealing the semiconductor chip 12 and the passive components 14 and 15, the silica filler present on a surface of the sealing resin 19 is dissolved with a hydrogen fluoride solution, and a shield layer 21 which is electrically connected to the ground terminal 38 is then formed on the surface of the sealing resin 19 by a plating method.

The present invention relates to a method of manufacturing a semiconductor device, and more particularly to a method of manufacturing a semiconductor device having an electronic component mounted on a wiring board and a sealing resin containing a silica filler for sealing the electronic component.

A conventional semiconductor device includes a semiconductor device (see FIG. 1) comprising an electromagnetic wave absorbing sheet having the function of blocking an electromagnetic wave.

FIG. 1 is a sectional view showing the conventional semiconductor device.

With reference to FIG. 1, a conventional semiconductor device 100 comprises a wiring board 101, a semiconductor chip 103 and passive components 104 and 105 which are electronic components, a sealing resin 107, and an electromagnetic wave absorbing sheet 108.

The wiring board 101 has a board body 111, through vias 113 to 115 provided to penetrate through the board body 111, wiring patterns 117 to 119 provided on an upper surface 111A of the board body 111, and external connecting pads 121 to 123 provided on a lower surface 111B of the board body 111.

The through via 113 has one of ends connected to the wiring pattern 117 and the other end connected to the external connecting pad 121. The through via 114 has one of ends connected to the wiring pattern 118 and the other end connected to the external connecting pad 122. The through via 115 has one of ends connected to the wiring pattern 119 and the other end connected to the external connecting pad 123.

The semiconductor chip 103 is bonded to the upper surface 111A of the board body 111. The semiconductor chip 103 has an electrode pad 125A connected to one of ends of a metal wire 109A and an electrode pad 125B connected to one of ends of a metal wire 109B. The other end of the metal wire 109A is connected to the wiring pattern 117 and the other end of the metal wire 109B is connected to the wiring pattern 118. In other words, the semiconductor chip 103 is connected to the wiring board 101 through wire bonding.

The passive component 104 is provided on the wiring pattern 118. The passive component 104 is electrically connected to the wiring pattern 118. The passive component 105 is provided on the wiring pattern 119. The passive component 105 is electrically connected to the wiring pattern 119.

The sealing resin 107 is provided on the upper surface 111A of the board body 111 in order to seal the semiconductor chip 103, the passive components 104 and 105, and the metal wires 109A and 109B. The upper surface 107A of the sealing resin 107 is a flat surface. It is preferable that the sealing resin 107 should feature a high moisture resistance and a small coefficient of thermal expansion. In order to implement the characteristic, approximately 70% of a silica filler is contained in a resin constituting the sealing resin 107. It is hard to roughen a surface of the sealing resin 107 containing the silica filler in a large amount through a conventional resin surface roughening treatment (a treatment carried out through permanganate etching, for example) (a silica content is large and a roughed shape cannot be controlled). For this reason, it is impossible to form a metal film on the surface of the sealing resin 107.

The electromagnetic wave absorbing sheet 108 is stuck to the upper surface 107A of the sealing resin 107. The electromagnetic wave absorbing sheet 108 is a sheet obtained by containing a metal filler having a high initial permeability in a resin provided on an adhesive sheet. The electromagnetic wave absorbing sheet 108 has a function of blocking an electromagnetic wave.

FIGS. 2 to 5 are views showing the steps of manufacturing the conventional semiconductor device. In FIGS. 2 to 5, the same components as those in the conventional semiconductor device 100 have the same reference numerals.

With reference to FIGS. 2 to 5, description will be given to a method of manufacturing the conventional semiconductor device 100. First of all, at the step shown in FIG. 2, the wiring board 101 is formed by a well-known technique. At the step shown in FIG. 3, next, the semiconductor chip 103 is connected to the wiring patterns 117 and 118 through the wire bonding and the passive component 104 is mounted on the wiring pattern 118, and furthermore, the passive component 105 is mounted on the wiring pattern 119.

At the step shown in FIG. 4, subsequently, the sealing resin 107 for sealing the semiconductor chip 103, the passive components 104 and 105 and the metal wires 109A and 109B is formed. As shown in FIG. 5, then, the electromagnetic wave absorbing sheet 108 is stuck to the upper surface 107A of the sealing resin 107. Consequently, there is manufactured the semiconductor device 100 having the function of blocking an electromagnetic wave (for example, see Patent Document 1).

### [Patent Document 1] JP-A-2002-176284

However, the electromagnetic wave absorbing sheet 108 is expensive. For this reason, there is a problem in that the use of the electromagnetic wave absorbing sheet 108 causes a cost of the semiconductor device 100 to be increased.

### SUMMARY OF THE INVENTION

In consideration of the problems, therefore, it is an object of the invention to provide a method of manufacturing a semiconductor device capable of reducing a cost of the semiconductor device having a shielding function for blocking an electromagnetic wave.

According to a first aspect of the invention, there is provided a method of manufacturing a semiconductor device including a wiring board having a ground terminal, an electronic component mounted on the wiring board, and a sealing resin containing a silica filler for sealing the electronic component, the method including:

a silica dissolving step of dissolving the silica filler present on a surface of the sealing resin with a hydrogen fluoride solution; and

a shield layer forming step of forming a shield layer which is electrically connected to the ground terminal on the surface of the sealing resin by a plating method after the silica dissolving step.

According to a second aspect of the invention, there is provided the method of manufacturing a semiconductor device according to the first aspect, further including:

a cleaning step of cleaning the surface of the sealing resin before the silica dissolving step.

According to the invention, the silica filler present on the surface of the sealing resin is dissolved in a hydrogen fluoride solution. Consequently, it is possible to roughen the surface of the sealing resin. By a plating method which is more inexpensive than the electromagnetic wave absorbing sheet, thus, a shield layer connected electrically to the ground terminal can be formed on the surface of the roughened sealing resin. Therefore, it is possible to reduce the cost of the semiconductor device.

According to the invention, it is possible to reduce a cost of a semiconductor device having a shielding function for blocking an electromagnetic wave.

### BRIEF DESCRIPTION OF THE DRAWINGS

FIG. 1 is a sectional view showing a conventional semiconductor device,

FIG. 2 is a view (No. 1) showing a step of manufacturing the conventional semiconductor device,

FIG. 3 is a view (No. 2) showing a step of manufacturing the conventional semiconductor device,

FIG. 4 is a view (No. 3) showing a step of manufacturing the conventional semiconductor device,

FIG. 5 is a view (No. 4) showing a step of manufacturing the conventional semiconductor device,

FIG. 6 is a sectional view showing a semiconductor device according to a first embodiment of the invention,

FIG. 7 is a view (No. 1) showing a step of manufacturing the semiconductor device according to the first embodiment of the invention,

FIG. 8 is a view (No. 2) showing a step of manufacturing the semiconductor device according to the first embodiment of the invention,

FIG. 9 is a view (No. 3) showing a step of manufacturing the semiconductor device according to the first embodiment of the invention,

FIG. 10 is a view (No. 4) showing a step of manufacturing the semiconductor device according to the first embodiment of the invention,

FIG. 11 is a view (No. 5) showing a step of manufacturing the semiconductor device according to the first embodiment of the invention,

FIG. 12 is a view (No. 6) showing a step of manufacturing the semiconductor device according to the first embodiment of the invention,

FIG. 13 is a view (No. 7) showing a step of manufacturing the semiconductor device according to the first embodiment of the invention,

FIG. 14 is a view (No. 8) showing a step of manufacturing the semiconductor device according to the first embodiment of the invention,

FIG. 15 is a view (No. 9) showing a step of manufacturing the semiconductor device according to the first embodiment of the invention,

FIG. 16 is a sectional view showing a semiconductor device according to a second embodiment of the invention, and

FIG. 17 is a sectional view showing a semiconductor device according to a third embodiment of the invention.

### DETAILED DESCRIPTION OF THE PREFERRED EMBODIMENTS

Next, embodiments according to the invention will be described with reference to the drawings.

### First Embodiment

FIG. 6 is a sectional view showing a semiconductor device according to a first embodiment of the invention.

With reference to FIG. 6, a semiconductor device 10 according to the first embodiment comprises a wiring board 11, a semiconductor chip 12 and passive components 14 and 15 which are electronic components, metal wires 16 and 17, a sealing resin 19 and a shield layer 21.

The wiring board 11 has a board body 23, through vias 25 to 27, wiring patterns 31 to 33, external connecting pads 35 to 37, and a ground terminal 38.

The board body 23 is a plate-shaped core board. Through holes 34A to 34C are formed on the board body 23. A glass epoxy substrate can be used for the board body 23, for example.

The through via 25 is provided on the through hole 34A. The through via 25 has one of ends connected to the wiring pattern 31 and the other end connected to the external connecting pad 35. The through via 26 is provided on the through hole 34B. The through via 26 has one of ends connected to the wiring pattern 32 and the other end connected to the external connecting pad 36. The through via 27 is provided on the through hole 34C. The through via 27 has one of ends connected to the wiring pattern 33 and the other end connected to the external connecting pad 37.

The wiring pattern 31 is provided on an upper surface 23A of the board body 23 in a portion corresponding to a position in which the through via 25 is formed. The wiring pattern 31 is connected to the through via 25. The wiring pattern 32 is provided on the upper surface 23A of the board body 23 in a portion corresponding to a position in which the through via 26 is formed. The wiring pattern 32 is connected to the through via 26. The wiring pattern 33 is provided on the upper surface 23A of the board body 23 in a portion corresponding to a position in which the through via 27 is formed. The wiring pattern 33 is connected to the through via 27.

The external connecting pad 35 is provided on the lower surface 23B of the board body 23 in the portion corresponding to the position in which the through via 25 is formed. The external connecting pad 35 is connected to the through via 25. The external connecting pad 35 is electrically connected to the wiring pattern 31 through the through via 25.

The external connecting pad 36 is provided on the lower surface 23B of the board body 23 in the portion corresponding to the position in which the through via 26 is formed. The external connecting pad 36 is connected to the through via 26. The external connecting pad 36 is electrically connected to the wiring pattern 32 through the through via 26.

The external connecting pad 37 is provided on the lower surface 23B of the board body 23 in the portion corresponding to the position in which the through via 27 is formed. The external connecting pad 37 is connected to the through via 27. The external connecting pad 37 is electrically connected to the wiring pattern 33 through the through via 27.

The ground terminal 38 is set to have a ground potential and is provided on the upper surface 23A of the board body 23. The ground terminal 38 is connected to the shield layer 21.

The semiconductor chip 12 is bonded to the upper surface 23A of the board body 23. The semiconductor chip 12 has a semiconductor substrate (not shown), an integrated circuit (not shown) formed on the semiconductor substrate, and electrode pads 41 and 42 connected electrically to the integrated circuit. The electrode pad 41 is electrically connected to the wiring pattern 31 through the metal wire 16, and the electrode pad 42 is electrically connected to the wiring pattern 32 through the metal wire 17. In other words, the semiconductor chip 12 is connected to the wiring board 11 through wire bonding.

The passive component 14 is fixed onto the wiring pattern 32 and is electrically connected to the wiring pattern 32. The passive component 15 is fixed onto the wiring pattern 33 and is electrically connected to the wiring pattern 33. As the passive components 14 and 15, it is possible to use a chip resistor, a chip capacitor or a crystal resonator, for example.

The metal wire 16 has one of ends connected to the electrode pad 41 and the other end connected to the wiring pattern 31. The metal wire 17 has one of ends connected to the electrode pad 42 and the other end connected to the wiring pattern 32.

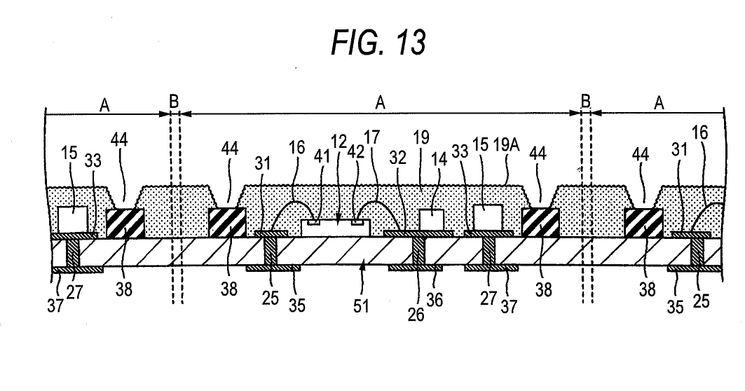

The sealing resin 19 is provided on the upper surface 23A side of the board body 23 in order to seal the semiconductor chip 12, the passive components 14 and 15, and the metal wires 16 and 17. An upper surface 19A of the sealing resin 19 is a flat surface. The sealing resin 19 has an opening portion 44 for exposing an upper surface of the ground terminal 38. It is preferable that the sealing resin 19 should feature an excellent moisture absorbing property and a small coefficient of thermal expansion. In order to implement the characteristics, approximately 70% of a silica filler is contained in a resin constituting the sealing resin 19. As the resin constituting the sealing resin 19, it is possible to use a phenolic curing resin, for example. The silica filler is dissolved in a surface of the sealing resin 19 which corresponds to a region in which the shield layer 21 is formed (specifically, the upper surface 19A of the sealing resin 19 and a surface of the sealing resin 19 which constitutes the opening portion 44) with a hydrogen fluoride solution and the same surface is thus roughened (see FIG. 13). The sealing resin 19 can be formed by a transfer molding method, for example.

The shield layer 21 is provided on the surface of the sealing resin 19 subjected to the roughening treatment. The shield layer 21 has a via portion 46 and a shield layer body 47. The via portion 46 is provided in the opening portion 44. A lower end of the via portion 46 is connected to the ground terminal 38 and an upper end of the via portion 46 is connected to the shield layer body 47. The shield layer body 47 is provided on the upper surface 19A of the sealing resin 19 subjected to the roughening treatment. The shield layer body 47 is constituted integrally with the via portion 46 and is electrically connected to the ground terminal 38 through the via portion 46. Consequently, the shield layer body 47 is set to have a ground potential. The shield layer 21 serves to block electromagnetic waves discharged from the semiconductor chip 12 and the passive components 14 and 15 and to block electromagnetic waves discharged from other devices (not shown) which are present on an outside of the semiconductor device 10, thereby preventing the semiconductor chip 12 and the passive components 14 and 15 from being adversely influenced by the electromagnetic waves discharged from the other devices.

As a material of the shield layer 21, for example, it is possible to use a metal having such a characteristic as to block an electromagnetic wave. Specifically, it is preferable to use a metal having a high conductivity (a specific volume resistance of 3×10⁻⁸ Ω·m or less) or a metal having a high initial permeability (a metal having an initial permeability of 150 or more).

As the metal having a high conductivity, it is possible to use Cu, for example. As the metal having a high initial permeability, moreover, it is possible to use Ni, for example.

The shield layer 21 can be formed through a nonelectrolytic plating method or a method obtained by combining the nonelectrolytic plating method and an electrolytic plating method. As a specific shield layer, for example, it is possible to use an Ni film or a Cu film which is formed by the nonelectrolytic plating method or a laminated film in which a Cu film formed by the electrolytic plating method is provided on an Ni film formed by the nonelectrolytic plating method.

In the case in which the Ni film is used as the shield layer 21, a thickness M1 of the shield layer body 47 can be set to be 0.5 μm, for example. In the case in which an Ni film/Cu laminated film is used as the shield layer 21, moreover, the thickness M1 of the shield layer body 47 can be set to be 2.0 μm, for example. In this case, a thickness of the Ni film can be set to be 1.0 μm, for example, and a thickness of the Cu film can be set to be 1.0 μm, for example.

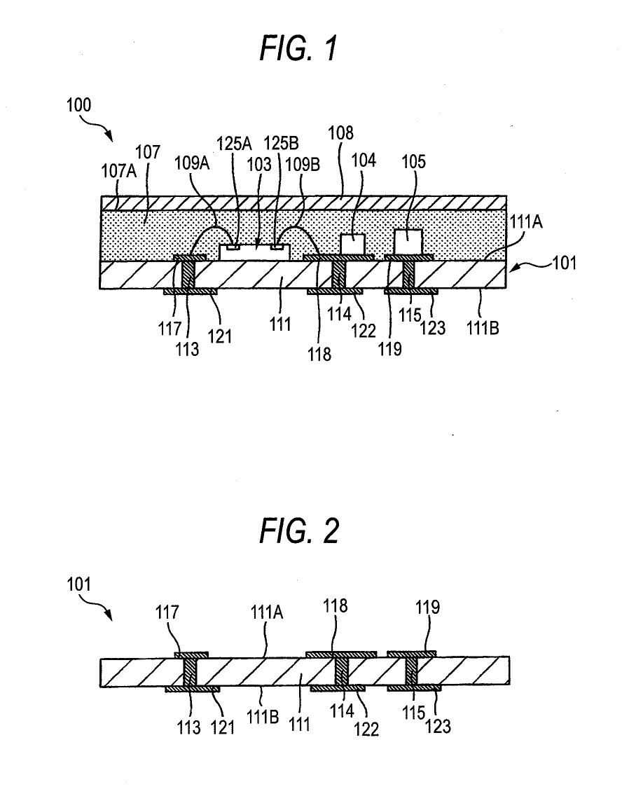

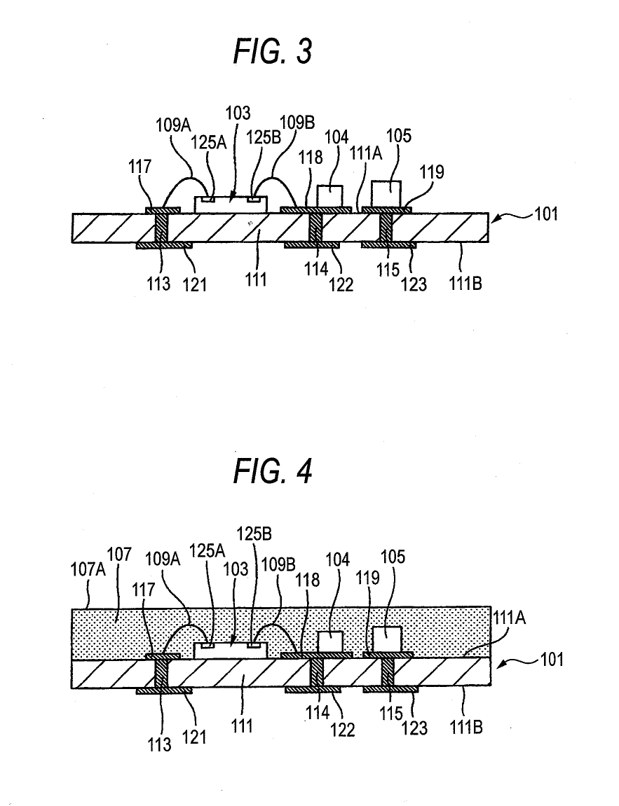

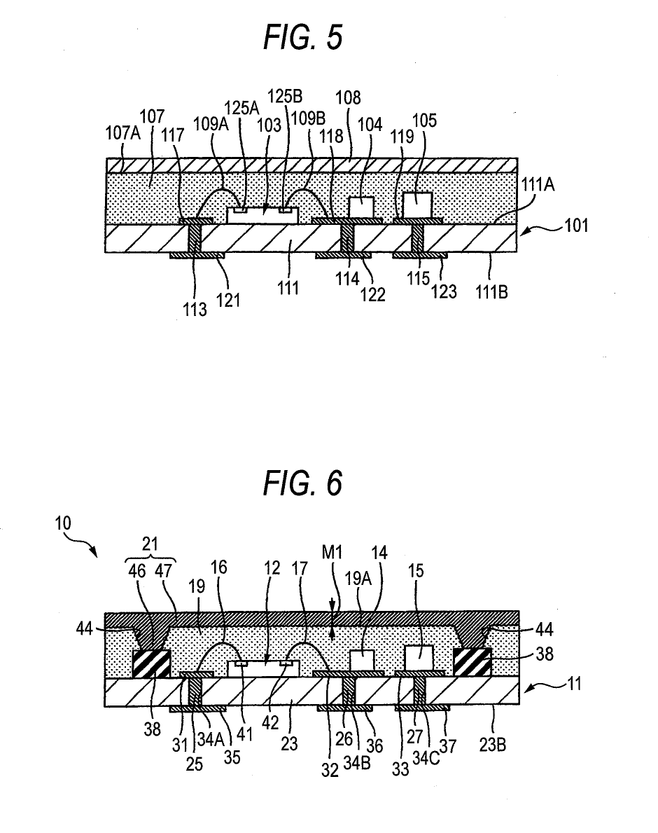

According to the semiconductor device in accordance with the embodiment, the shield layer 21 formed by the plating method is provided on the sealing resin 19 subjected to the roughening treatment. Consequently, it is possible to reduce the cost of the semiconductor device 10 more greatly as compared with the conventional semiconductor device 100 comprising the expensive electromagnetic wave absorbing sheet 108 (see FIG. 1).

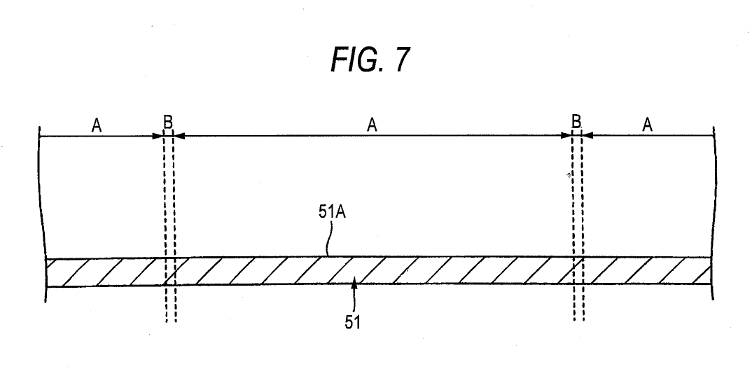

FIGS. 7 to 15 are views showing the steps of manufacturing the semiconductor device according to the first embodiment of the invention. In FIGS. 7 to 15, the same components as those in the semiconductor device 10 according to the first embodiment have the same reference numerals.

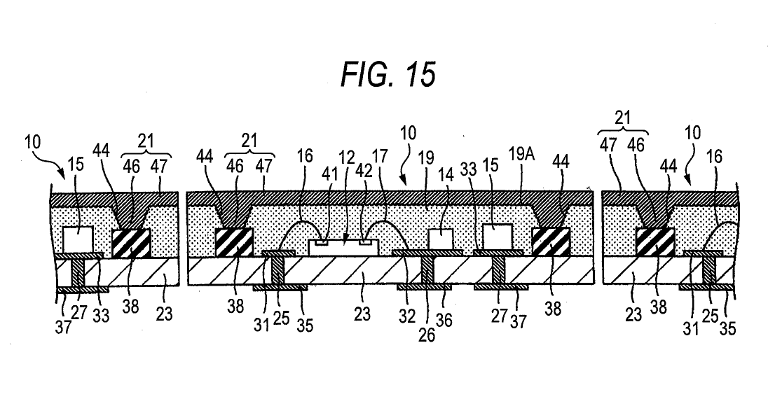

With reference to FIGS. 7 to 15, description will be given to a method of manufacturing the semiconductor device 10 according to the first embodiment. First of all, at the step shown in FIG. 7, there is prepared a substrate 51 having a plurality of semiconductor device formation regions A in which the semiconductor device 10 is to be formed. The semiconductor device formation regions A are isolated from each other through a cutting region B. A portion corresponding to the cutting region B is cut so that the substrate 51 is changed into a plurality of substrate bodies 23 (see FIG. 6) at the step shown in FIG. 15 which will be described below. As the substrate 51, it is possible to use a glass epoxy substrate, for example.

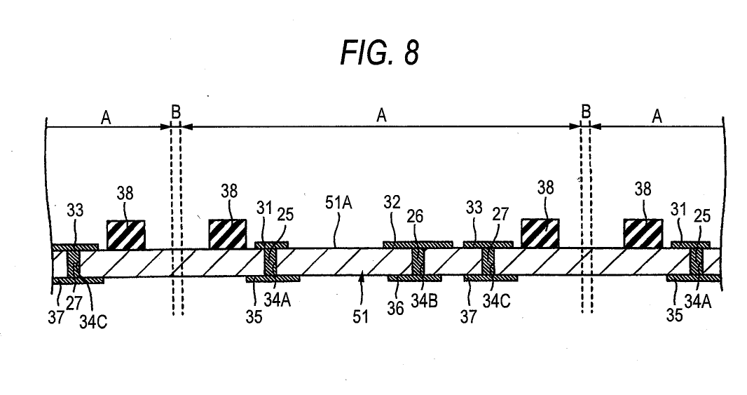

At the step shown in FIG. 8, next, the through holes 34A to 34C, the through vias 25 to 27, the wiring patterns 31 to 33, the external connecting pads 35 to 37 and the ground terminal 38 are formed on the substrate 51 in the portion corresponding to the semiconductor device formation region A by a well-known technique. Consequently, a structure corresponding to the wiring board 11 is formed on the substrate 51 in the portion corresponding to the semiconductor device formation regions A.

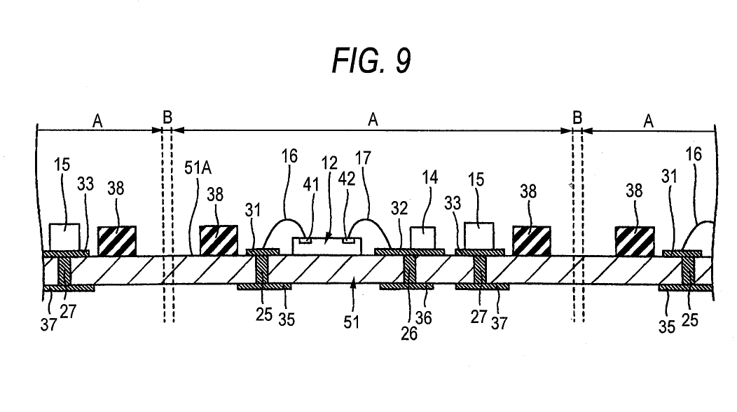

At the step shown in FIG. 9, subsequently, the semiconductor chip 12 is bonded to the upper surface 51A of the substrate 51 in the portion corresponding to the semiconductor device formation region A and is connected to the wiring patterns 31 and 32 through wire bonding (the wires 16 and 17), and furthermore, the passive component 14 is mounted on the wiring pattern 32 and the passive component 15 is mounted on the wiring pattern 33.

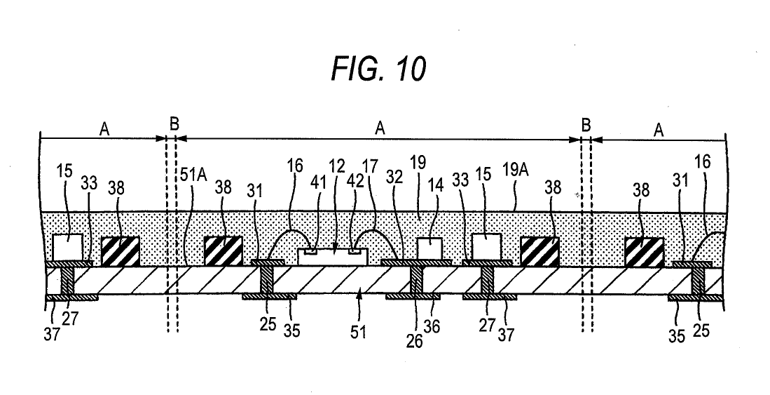

At the step shown in FIG. 10, then, the sealing resin 19 having the flat upper surface 19A is formed to cover the whole upper surface side of the structure shown in FIG. 9. Consequently, there are sealed the semiconductor chip 12, the passive components 14 and 15, the wires 16 and 17, and the ground terminal 38 which are provided in the semiconductor device formation regions A. The sealing resin 19 can be formed by a transfer molding method, for example. The sealing resin 19 is a mold resin having a high moisture resistance, and approximately 70% of a silica filler is contained in a resin constituting the sealing resin 19. As the resin constituting the sealing resin 19, it is possible to use a phenolic curing resin, for example.

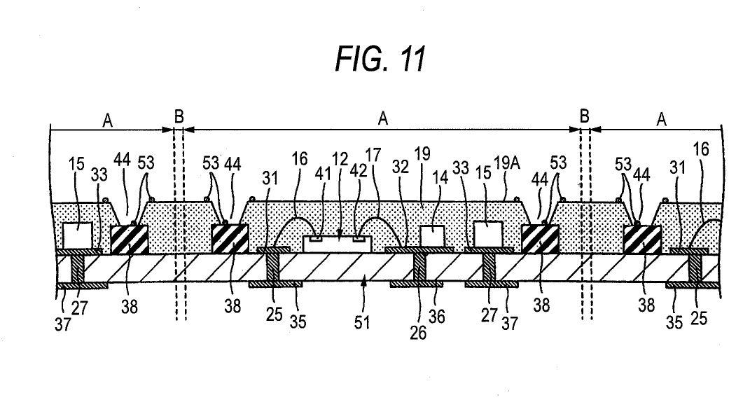

At the step shown in FIG. 11, thereafter, the opening portion 44 for exposing the upper surface of the ground terminal 38 is formed in the sealing resin 19. At this time, a resin residue 53 is generated on the surface of the sealing resin 19 (specifically, the upper surface 19A of the sealing resin 19 and the surface of the sealing resin 19 which constitutes the opening portion 44) and/or the ground terminal 38 when the opening portion 44 is processed. The opening portion 44 can be formed by a method such as a laser processing or drilling.

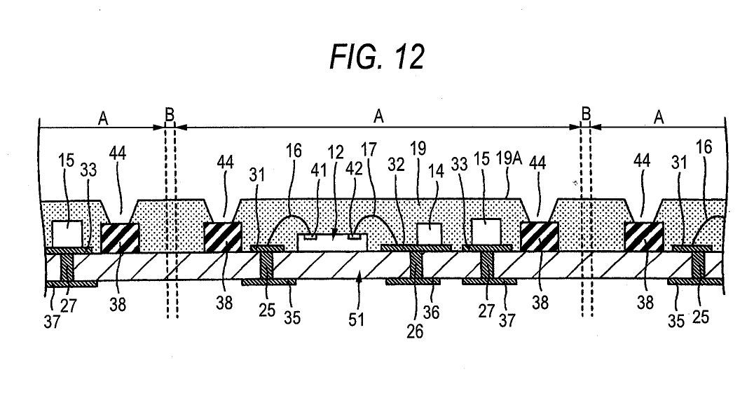

At the step shown in FIG. 12, next, the resin residue 53 generated on the surface of the sealing resin 19 and the ground terminal 38 and a natural oxide film formed on the surface of the sealing resin 19 are removed with a cleaning fluid, and subsequently, the cleaning fluid remaining on the surface of the sealing resin 19 and the ground terminal 38 is removed with a neutralizing fluid (a cleaning step). Specifically, a cleaning fluid obtained by dissolving sodium permanganate (a concentration of 60 g/L) and sodium hydroxide (a concentration of 40 g/L) in pure water is heated to 80° C. and the structure shown in FIG. 11 is immersed in the heated cleaning fluid for 10 minutes to remove the resin residue 53, for example. Then, a neutralizing fluid obtained by mixing sulfuric acid (a concentration of 50 ml/L), glyoxal (a concentration of 7 ml/L) and pure water is heated to 35° C. and the structure shown in FIG. 11 which is subjected to the cleaning treatment is immersed in the heated neutralizing solution for five minutes to remove the residue generated on the surface of the sealing resin 19 and the ground terminal 38.

Thus, the cleaning treatment is carried out before the formation of the shield layer 21 so that the resin residue 53 is removed. Therefore, it is possible to sufficiently maintain a conduction between the shield layer 21 and the ground terminal 38. By the execution of the cleaning treatment, moreover, the resin covering the silica filler is removed. At the step shown in FIG. 13 which will be described below, therefore, the silica filler present on the surface of the sealing resin 19 is easily dissolved.

At the step shown in FIG. 13, next, the silica filler present on the surface of the sealing resin 19 (specifically, the upper surface 19A of the sealing resin 19 and the surface of the sealing resin 19 which constitutes the opening portion 44) is dissolved with a hydrogen fluoride solution to roughen the surface of the sealing resin 19 (a silica dissolving step). More specifically, the structure shown in FIG. 12 is immersed for 5 to 10 minutes in a hydrogen fluoride solution (a temperature of 23° C., for example) diluted into a concentration of 10 wt % with pure water and the silica filler present on the surface of the sealing resin 19 is thus dissolved.

By dissolving the silica filler present on the surface of the sealing resin 19 with the hydrogen fluoride solution, thus, it is possible to roughen the surface of the sealing resin 19 on which the shield layer 21 is formed. Consequently, it is possible to directly form a metal film on the surface of the sealing resin 19 by using a nonelectrolytic plating method.

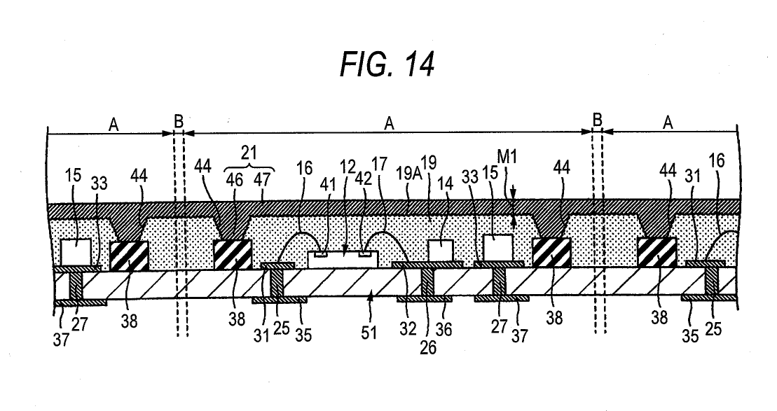

At the step shown in FIG. 14, subsequently, the opening portion 44 is filled and a metal film is deposited and grown to cover the upper surface 19A of the sealing resin 19 by a plating method so that the shield layer 21 including the via portion 46 and the shield layer body 47 is formed (a shield layer forming step). As a metal constituting the metal film, it is possible to use a metal having a characteristic for blocking an electromagnetic wave, for example. More specifically, it is preferable to use a metal having a high conductivity (a specific volume resistance of 3×10⁻⁸ Ω·m or less) or a metal having a high initial permeability (a metal having an initial permeability of 150 or more). As the metal having a high conductivity, it is possible to use Cu, for example. As the metal having a high permeability, moreover, it is possible to use Ni, for example.

Specifically, the shield layer 21 is formed by carrying out a well-known nonelectrolytic plating pretreatment such as an oxide film formation preventing treatment for preventing a natural oxide film from being formed or a treatment for applying a catalyst over the surface of the sealing resin 19 of the structure shown in FIG. 13 and then depositing and growing the Ni film on the surface 19A of the sealing resin 19 by a nonelectrolytic plating method, for example. In this case, the thickness M1 of the shield layer body 47 can be set to be 0.5 μm, for example. If necessary, moreover, it is also possible to further form an Ni film by an electrolytic plating method on the Ni film formed by the nonelectrolytic plating method.

The shield layer 21 may be a laminated film having a different film type. More specifically, it is also possible to constitute the shield layer 21 by forming an Ni film having a thickness of 0.5 μm on the surface of the sealing resin 19 through the nonelectrolytic plating method and then forming a Cu film having a thickness of 1.0 μm on the Ni film through the electrolytic plating method, for example. In this case, the thickness of the Ni film can beset to be 1.0 μm, for example, and the thickness of the Cu film can be set to be 1.0 μm, for example.

Thus, the shield layer 21 is formed on the surface of the sealing resin 19 through the plating method. As compared with the conventional semiconductor device 100 comprising the expensive electromagnetic wave absorbing sheet 108 (see FIG. 1), consequently, it is possible to reduce the cost of the semiconductor device 10 more greatly.

At the step shown in FIG. 15, subsequently, the shield layer body 47, the sealing resin 19 and the substrate 51 in the portion corresponding to the cutting region B are cut. Consequently, a plurality of semiconductor devices 10 is manufactured.

According to the method of manufacturing a semiconductor device in accordance with the embodiment, the silica filler present on the surface of the sealing resin 109 is dissolved with the hydrogen fluoride solution to roughen the surface of the sealing resin 19 and the shield layer 21 is then formed on the surface of the roughened sealing resin 19 through a more inexpensive plating method than the electromagnetic wave absorbing sheet 108. Therefore, it is possible to reduce the cost of the semiconductor device 10 more greatly as compared with the conventional semiconductor device 100 (see FIG. 1) comprising the electromagnetic wave absorbing sheet 108.

### Second Embodiment

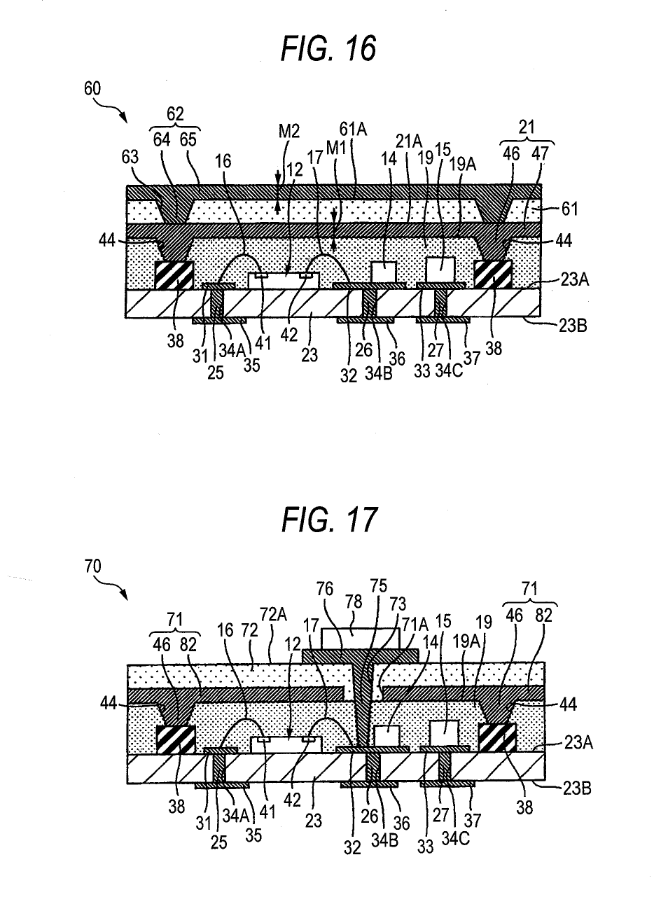

FIG. 16 is a sectional view showing a semiconductor device according to a second embodiment of the invention. In FIG. 16, the same components as those in the semiconductor device 10 according to the first embodiment have the same reference numerals.

With reference to FIG. 16, a semiconductor device 60 according to the second embodiment has the same structure as the semiconductor device 10 except that a buildup resin 61 and an antenna pattern 62 are further provided in the structure of the semiconductor device 10 according to the first embodiment.

The buildup resin 61 is provided to cover an upper surface 21A of a shield layer 21. An opening portion 63 for exposing a part of the upper surface 21A of the shield layer 21 is formed on the buildup resin 61. The buildup resin 61 is a resin which can be subjected to a conventional resin surface roughening treatment (more specifically, a permanganate etching treatment, for example). A surface of the buildup resin 61 (specifically, an upper surface 61A of the buildup resin 61 and a surface of the buildup resin 61 which constitutes the opening portion 63) is roughened.

The antenna pattern 62 is provided on the surface of the buildup resin 61 which is subjected to the roughening treatment. The antenna pattern 62 has a via portion 64 and an antenna pattern body 65. The via portion 64 is provided in the opening portion 63 which is subjected to the roughening treatment. A lower end of the via portion 64 is connected to a shield layer 21 and an upper end of the via portion 64 is connected to the antenna pattern body 65. The antenna pattern body 65 is provided to cover the upper surface 61A of the buildup resin 61 which is subjected to the roughening treatment. The antenna pattern body 65 is constituted integrally with the via portion 64. As a material of the antenna pattern 62, it is possible to use a metal. More specifically, Cu can be used, for example. The antenna pattern 62 can be formed by a method such as plating, evaporation or sputtering. In the case in which Cu is used as the material of the antenna pattern 62, moreover, a thickness M2 of the antenna pattern body 65 can be set to be 1.0 μm, for example.

According to the semiconductor device in accordance with the embodiment, the buildup resin 61 and the antenna pattern 62 are laminated on the shield layer 21 which is directly provided on the sealing resin 19. Consequently, it is possible to enhance a mounting density of the semiconductor device 60.

### Third Embodiment

FIG. 17 is a sectional view showing a semiconductor device according to a third embodiment of the invention. In FIG. 17, the same components as those in the semiconductor device 10 according to the first embodiment have the same reference numerals.

With reference to FIG. 17, a semiconductor device 70 according to the third embodiment has the same structure as the semiconductor device 10 except that a shield layer 71 is provided in place of the shield layer 21 provided in the semiconductor device 10 according to the first embodiment, and furthermore, a buildup resin 72, an opening portion 73, a via 75, a wiring pattern 76 and an electronic component 78 are provided.

The shield layer 71 is provided on a surface of a sealing resin 19 (specifically, an upper surface 19A of the sealing resin 19 and a surface of the sealing resin 19 which constitutes an opening portion 44). The shield layer 71 has the same structure as the shield layer 21 except that a shield layer body 82 is provided in place of the shield layer body 47 disposed in the shield layer 21 described in the first embodiment. The shield layer body 82 has the same structure as the shield layer body 47 except that an opening portion 71A for exposing a part of the upper surface 19A of the sealing resin 19 is provided on the shield layer body 47 described in the first embodiment. The opening portion 71A is formed to penetrate through the shield layer body 82. The opening portion 71A causes the via 75 to pass therethrough, and a diameter of the opening portion 71A is formed to be greater than that of the via 75.

The buildup resin 72 is provided to fill in the opening portion 71A and to cover an upper surface of the shield layer body 82. The buildup resin 72 can be subjected to a conventional resin surface roughening treatment (specifically, a permanganate etching treatment, for example). An upper surface 72A of the buildup resin 72 is roughened.

The opening portion 73 serves to provide the via 75 for electrically connecting a wiring pattern 32 to the wiring pattern 76. The opening portion 73 is formed to penetrate through the sealing resin 19 and the buildup resin 72 in a portion positioned between the wiring pattern 32 and the wiring pattern 76. The opening portion 73 exposes an upper surface of the wiring pattern 32. A surface of the sealing resin 19 in a portion constituting the opening portion 73 and a surface of the buildup resin 72 are subjected to the roughening treatment.

The via 75 is provided on the opening portion 73. A lower end of the via 75 is connected to the wiring pattern 32 and an upper end of the via 75 is connected to the wiring pattern 76. Consequently, the wiring pattern 32 and the wiring pattern 76 are electrically connected to each other.

The wiring pattern 76 is provided on the upper surface 72A of the buildup resin 72 in a portion corresponding to a position in which the via 75 is to be formed. The wiring pattern 76 is constituted integrally with the via 75. As materials of the via 75 and the wiring pattern 76, it is possible to use Cu, for example. The via 75 and the wiring pattern 76 can be formed at the same time by a plating method, for example.

The electronic component 78 is mounted on the wiring pattern 76. The electronic component 78 is electrically connected to the wiring pattern 76. The electronic component 78 is electrically connected to the wiring pattern 32 through the wiring pattern 76 and the via 75. As the electronic component 78, it is possible to use a semiconductor chip or a passive component, for example. As the passive component, it is possible to use a chip resistor, a chip capacitor or a crystal resonator, for example.

According to the semiconductor device in accordance with the embodiment, the buildup resin 71 and the wiring pattern 76 are laminated on the shield layer 21 which is directly provided on the sealing resin 19, and furthermore, the electronic component 78 mounted on the wiring pattern 76 is provided so that a mounting density of the semiconductor device 70 can be enhanced.

While the preferred embodiments according to the invention have been described above in detail, the invention is not restricted to the specific embodiments but various modifications and changes can be made without departing from the scope of the invention described in the claims.

The invention can be applied to a method of manufacturing a semiconductor device having an electronic component mounted on a wiring board and a sealing resin containing a silica filler for sealing the electronic component.

What is claimed is:

1. A method of manufacturing a semiconductor device including a wiring board having a ground terminal, an electronic component mounted on the wiring board, and a sealing resin containing a silica filler for sealing the electronic component, the method comprising:
a silica dissolving step of dissolving the silica filler present on a surface of the sealing resin with a hydrogen fluoride solution; and
a shield layer forming step of forming a shield layer which is electrically connected to the ground terminal on the surface of the sealing resin by a plating method after the silica dissolving step.

2. The method of manufacturing a semiconductor device according to claim 1, further comprising:
a cleaning step of cleaning the surface of the sealing resin before the silica dissolving step.
